(19) United States
(12) Patent Application Publication
(10) Pub. No.: US 2012/0224441 A1
(43) Pub. Date: Sep. 6, 2012

(54) SEMICONDUCTOR MEMORY APPARATUS

(75) Inventors: Jae Bum KO, Ichon-shi (KR); Sang Jin BYEON, Ichon-shi (KR)

(73) Assignee: Hynix Semiconductor Inc., Ichon-shi (KR)

(21) Appl. No.: 13/171,885

(22) Filed: Jun. 29, 2011

(30) Foreign Application Priority Data
Mar. 4, 2011 (KR) 10-2011-0019324

(51) Int. Cl. G11C 7/00

(52) U.S. Cl. 365/191

(57) ABSTRACT

Various embodiments of a semiconductor memory apparatus are disclosed. In one exemplary embodiment, a semiconductor memory apparatus may include a page size control unit configured to generate first and second block enable signals having a level corresponding to one of a plurality of row selection signals or one of a plurality of column selection signals based on a page size control signal; a first page block configured to enable a plurality of first memory cells selected by the plurality of row selection signals in response to the first block enable signal, and activate data access of memory cells selected among the plurality of selected first memory cells by the plurality of column selection signals and the option column selection signal; and a second page block configured to enable a plurality of second memory cells selected by the plurality of row selection signals in response to the second block enable signal, and activate data access of memory cells selected among the plurality of selected second memory cells by the plurality of column selection signals and the option column selection signal.

### CROSS-REFERENCE TO RELATED APPLICATION

The present application claims priority under 35 U.S.C. §119(a) to Korean Patent Application No. 10-2011-0019324, filed on Mar. 4, 2011, in the Korean Intellectual Property Office, which is incorporated herein by reference in its entirety as if set forth in full.

### BACKGROUND

1. Technical Field

Various embodiments of the present disclosure relate to a semiconductor memory apparatus. In particular, certain embodiments relate to technology that enables data access by controlling a page size.

2. Related Art

In a semiconductor memory apparatus, the number of bits in simultaneously outputted data is determined according to a configuration of the bit organization. In general, a semiconductor memory apparatus is designed such that a variety of bit organizations, such as X4, X8, X16, and X32, can be flexibly selected. For example, after a semiconductor memory apparatus is designed to be compatible with a variety of bit organizations, a setting fuse is cut, and a bonding wire is selectively connected to select a bit organization.

For illustration purposes, a semiconductor apparatus having a storage capacity of 4 Gb and a total of 16 bits of an address supplied from outside, and being configured in an address multiplexing scheme where a row address and a column address are sequentially supplied together with the respective commands will be described as follows.

The semiconductor memory apparatus configured in the above-described manner may access a memory cell having a page size of 1K through a 16-bit row address and a 10-bit column address. At this time, when the storage capacity of the semiconductor memory apparatus is increased to 8 Gb, the bit number of the column address is increased to access a memory cell since the bit number of the row address is limited to 16.

Furthermore, when the bit organization is changed, an additional column address is assigned to access a memory cell. Since the storage capacity is increased to 8 Gb but the bit number of the row address is not increased, the semiconductor memory apparatus accesses a memory cell having a page size of 2K, resulting in a higher current consumption than a current consumption when accessing a memory cell having a page size of 1K.

### SUMMARY

Accordingly, there is a need for an improved semiconductor memory apparatus that may obviate one or more of the problems or deficiencies described above. For example, according to various exemplary aspects, the present disclosure may provide a semiconductor memory apparatus capable of freely converting a page size. Moreover, some exemplary aspects may provide a semiconductor memory apparatus capable of controlling data access according to a bit organization.

Although the present disclosure may obviate one or more of the above-mentioned problems or deficiencies, it should be understood that some aspects of the invention might not necessarily obviate one or more of those problems or deficiencies.

In the following description, certain aspects and embodiments will become evident. It should be understood that these aspects and embodiments are merely exemplary and the invention, in its broadest sense, could be practiced without having one or more features of these aspects and embodiments.

To attain the advantages and in accordance with the purpose of the invention, as embodied and broadly described herein, one aspect of the invention may provide a semiconductor memory apparatus comprising: a row selection signal generation unit configured to output a row address as a plurality of row selection signals in response to an active pulse signal; a column control unit configured to selectively assign and output a first or second column address bit signal of a column address as a bit organization control signal based on a page size control signal; a column selection signal generation unit configured to output the column address as a plurality of column selection signals in response to a column pulse signal, and output the bit organization control signal as an option column selection signal; a page size control unit configured to generate first and second block enable signals having a level corresponding to one of the plurality of row selection signals or one of the plurality of column selection signals based on the page size control signal; a first page block configured to enable a plurality of first memory cells selected by the plurality of row selection signals in response to the first block enable signal, and activate data access of memory cells selected among the plurality of selected first memory cells by the plurality of column selection signals and the option column selection signal; and a second page block configured to enable a plurality of second memory cells selected by the plurality of row selection signals in response to the second block enable signal, and activate data access of memory cells selected among the plurality of selected second memory cells by the plurality of column selection signals and the option column selection signal.

According to another exemplary aspect, a semiconductor memory apparatus may comprise: a page size control unit configured to generate first and second block enable signals having a level corresponding to one of a plurality of row selection signals or one of a plurality of column selection signals based on a page size control signal; a first page block configured to enable a plurality of first memory cells selected by the plurality of row selection signals in response to the first block enable signal, and activate data access of memory cells selected among the plurality of selected first memory cells by the plurality of column selection signals and the option column selection signal; and a second page block configured to enable a plurality of second memory cells selected by the plurality of row selection signals in response to the second block enable signal, and activate data access of memory cells selected among the plurality of selected second memory cells by the plurality of column selection signals and the option column selection signal.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

It is to be understood that both the foregoing general description and the following detailed description are exemplary and explanatory only and are not restrictive of the invention, as claimed.

### BRIEF DESCRIPTION OF THE DRAWINGS

The accompanying drawings, which are incorporated in and constitute a part of this specification, illustrate various embodiments consistent with the invention and, together with the description, serve to explain the principles of the invention.

FIG. 1 is a schematic diagram illustrating a configuration of a semiconductor memory apparatus according to one exemplary embodiment.

FIG. 2 is a circuit diagram illustrating an exemplary configuration of a column control unit of FIG. 1.

FIG. 3 is a circuit diagram illustrating an exemplary configuration of a page size control unit of FIG. 1.

### DETAILED DESCRIPTION

Reference will now be made in detail to the exemplary embodiments of a semiconductor memory apparatus consistent with the present invention, examples of which are illustrated in the accompanying drawings. Wherever possible, the same reference characters will be used throughout the drawings to refer to the same or like parts.

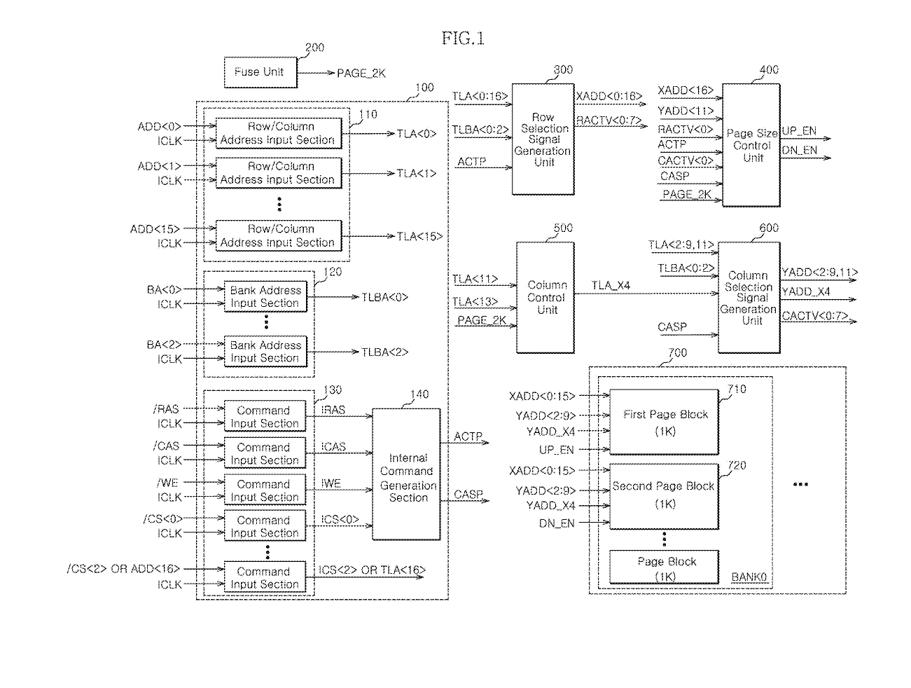

FIG. 1 is a schematic diagram illustrating a configuration of a semiconductor memory apparatus according to one exemplary embodiment. For purposes of clear explanation, the semiconductor memory apparatus of FIG. 1 only illustrates the components that are relevant to the technical idea of the present invention. Thus, the semiconductor memory apparatus of the present invention may additionally include one or more components that are not depicted in FIG. 1. Further, in some exemplary embodiments, one or more components illustrated in FIG. 1 may be omitted depending on the specific configuration of a semiconductor memory apparatus.

Referring to FIG. 1, the semiconductor memory apparatus may include a signal input unit 100, a fuse unit 200, a row selection signal generation unit 300, a page size control unit 400, a column control unit 500, a column selection signal generation unit 600, and a memory block 700. The memory block 700 and the page size control unit 400 may be independently provided. In some exemplary embodiments, the page size control unit 400 may be included in each bank of the memory block 700 depending on the desired configuration of the semiconductor apparatus.

The signal input unit 100 may include a row/column address input section 110, a bank address input section 120, a command input section 130, and an internal command generation section 140.

The memory block 700 may include a memory cell array (not illustrated) and is divided into a plurality of banks. In this exemplary embodiment, however, only first and second page blocks 710 and 720 included in a bank BANK0 are representatively illustrated. For reference, the 1K page size may refer to the number of memory cells (not illustrated) selected by one row selection signal. Therefore, when the first page block 710 is selected by a row selection signal, 1K memory cells are controlled. Furthermore, when the second page block 720 is selected by a row selection signal, 1K memory cells are controlled.

The detailed configuration and main operations of the semiconductor memory apparatus configured in such a manner will be described as follows.

The row/column address input unit 110 may be configured to buffer and store an external row address ADD<0:15> and an external column address ADD<2:9>, ADD<11>, and ADD<13> under the control of a clock signal ICLK, and output the stored signals as a row address TLA<0:15> and a column address TLA<2:9>, TLA<11>, and TLA<13>.

The external row address ADD<0:15> and the external column address ADD<2:9>, ADD<11>, and ADD<13> may be sequentially inputted. For example, the external row address ADD<0:15> and the external column address ADD<2:9>, ADD<11>, and ADD<13> are inputted through the address multiplexing scheme. Furthermore, although not illustrated in FIG. 1, the row address and the column address may be stored in a plurality of latches.

The bank address input unit 120 may be configured to buffer and store an external bank address BA<0:2> under the control of the clock signal ICLK, and output the stored signal as a bank address TLBA<0:2>. The memory cell array of the memory block 700 may be divided into a plurality of banks, and the bank address TLBA<0:2> may select any one of the banks such that data of memory cells in the selected bank can be accessed.

The command input unit 130 may be configured to buffer and store a plurality of external command signals /RAS, /CAS, /WE, and /CS<0:2> under the control of the clock signal ICLK, and output the stored signals as a plurality of command signals IRAS, ICAS, IWE, and ICD<0:2>.

The external command signal /CS<2> may be used as a chip select signal or external row address bit signal. For example, when the external command signal /CS<2> is not used as a chip select signal even though the external signal /CS<2> is assigned as a chip select signal, the external command signal /CS<2> may be used as an external row address bit signal. Therefore, when the external command signal /CS<2> is used as an external row address bit signal, a row address bit signal may be added to the existing row address TLA<0:15>, and thus a 17-bit row address TLA<0:16> may be used.

The internal command generation section 140 may be configured to decode the plurality of command signals IRAS, ICAS, IWE, and ICS<0:2> and output the decoded signals as internal commands ACTP and CASP.

In this exemplary embodiment, the internal commands may include an active pulse signal ACTP and a column pulse signal CASP. The active pulse signal ACTP is a signal for indicating an active operation, and the column pulse signal CASP is a signal for indicating a data read/write operation. That is, the active pulse signal ACTP is a control signal of the row area, and the column pulse signal CASP is a control signal of the column area.

The fuse unit 200 may be configured to control and output the level of a page size control signal PAGE_{—}2K according to the electrical state of a fuse. For example, when the page size control signal PAGE_{—}2K is at a first level (e.g., a high level), it may be an indication that a memory cell having a 2K page size is controlled to be accessed. When the page size control signal PAGE_{—}2K is at a second level (e.g., a low level), it may be an indication that a memory cell having a 1K page size is controlled to be accessed.

In an exemplary embodiment, the page size control signal PAGE_{—}2K may be generated by using a signal set in a mode register set (MRS).

The row selection signal generation unit 300 may be configured to output the row address TLA<0:16> as a plurality of row selection signals XADD<0:16> in response to the active pulse signal ACTP. For example, the row selection signal generation unit 300 may output the plurality of row selection signals XADD<0:16> when the active pulse signal ACTP pulses at a high level.

Furthermore, the row selection signal generation unit 300 may decode the bank address TLBA<0:2> and output a plurality of row bank selection signals RACTV<0:7>. In this exemplary embodiment, only a case in which the first bank BANK0 is selected is representatively illustrated. Therefore, the first row bank selection signal RACTV<0> is activated.

The column control unit 500 may be configured to selectively assign and output a first or second column address bit signal TLA<11> or TLA<13> of the column address TLA<2:9>, TLA<11>, and TLA<13> as a bit organization control signal TLA_X4 under the control of the page size control signal PAGE_{—}2K.

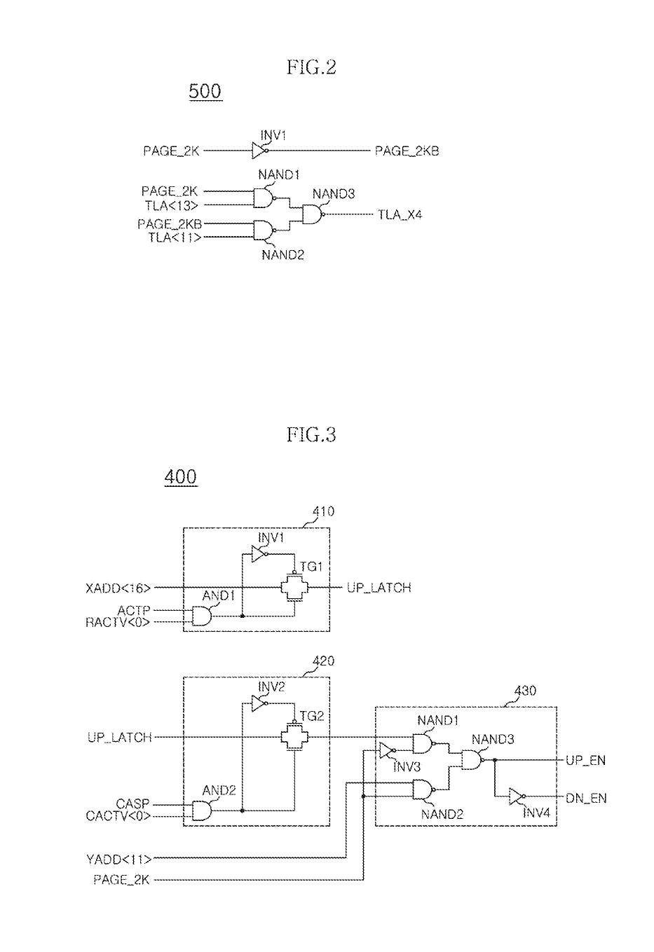

FIG. 2 is a circuit diagram illustrating an exemplary embodiment of the column control unit shown in FIG. 1. As shown in the figure, the column control unit 500 may include logic sections NAND1, NAND2, and NAND3 configured to logically combine the page size control signal PAGE_{—}2K, the first column address bit signal TLA<11>, and the second column address bit signal TLA<13> and output the combined signal as a bit organization control signal TLA_X4.

For example, the logic sections may include a first NAND section NAND1, a second NAND section NAND2, and a third NAND section NAND3. The first NAND section NAND1 is configured to receive the page size control signal PAGE_{—}2K and the second column address bit signal TLA<13>. The second NAND section NAND2 is configured to receive an inverted signal PAGE_{—}2 KB of the page size control signal PAGE_{—}2K and the first column address bit signal TLA<11>. The third NAND section NAND3 is configured to receive an output signal of the first NAND section NAND1 and an output signal of the second NAND section NAND2 and output the bit organization control signal TLA_X4.

When the page size control signal PAGE_{—}2K is at a low level, (e.g., when a memory cell having a 1K memory size is to be accessed), the column control unit 500 outputs the second column address bit signal TLA<13> as the bit organization control signal TLA_X4.

Referring to FIG. 1, the column selection signal generation unit 600 may be configured to output the column address TLA<2:9> and TLA<11> as a plurality of column selection signals YADD<2:9> and YADD<11> in response to the column pulse signal CASP.

Furthermore, the column selection signal generation unit 600 may be configured to receive the bit organization control signal TLA_X4 from the column control unit 500 and output it as an option column selection signal YADD_X4. For example, when the column pulse signal CASP pulses at a high level, the column selection signal generation unit 600 outputs the plurality of column selection signals YADD<2:9> and YADD<11> and the option column selection signal YADD_X4. The column selection signal generation unit 600 also decodes the bank address TLBA<0:2> and outputs a plurality of column bank selection signals CACTV<0:7>. In this exemplary embodiment, only a case in which the first bank BANK0 is selected has been representatively illustrated. Therefore, the first column bank selection signal CACTV<0> is activated.

The column selection signal generation unit 600 may be configured to output the column address TLA<2:9> and TLA<11>, excluding the most significant bit signal TLA<13>, as the plurality of column selection signals YADD<2:9> and YADD<11> and output the bit organization control signal TLA_X4 as the option column selection signal YADD_X4.

The page size control unit 400 may be configured to generate first and second block enable signals UP_EN and DN_EN having a level corresponding to any one row selection signal XADD<16> from the plurality of row selection signals XADD<0:16> under the control of the page size control signal PAGE_{—}2K. Alternatively, the page size control unit 400 may be configured to generate first and second block enable signals UP_EN and DN_EN having a level corresponding to any one column selection signal YADD<11> from the plurality of column selection signals YADD<2:9> and YADD<11> under the control of the page size control signal PAGE_{—}2K. Here, the first and second block enable signals UP_EN and DN_EN, as used herein, may be defined as signals having opposite levels.

The one row selection signal XADD<16> selected from the plurality of row selection signals XADD<0:16> may be a signal corresponding to the most significant row address bit signal TLA<16> of the row address TLA<0:16>. Similarly, the one column selection signal YADD<11> selected from the plurality of column selection signals YADD<2:9> and YADD<11> may be a signal corresponding to the column address bit signal TLA<11> neighboring the most significant address bit signal TLA<13> of the column address TLA<2:9>, TLA<11>, and TLA<13>.

FIG. 3 is a circuit diagram illustrating an exemplary embodiment of the page size control unit of FIG. 1. As shown in the figure, the page size control unit 400 may include a first logic section 410, a second logic section 420, and a third logic section 430.

The first logic section 410 may be configured to selectively output the row selection signal XADD<16> in response to the active pulse signal ACTP. For example, the row selection signal XADD<16> is inputted to a first transmission gate TG1 of the first logic section 410 and selectively outputted. The first transmission gate TG1 is configured to be turned on/off according to the control of an output signal of a first AND gate AND1 which is configured to receive the active pulse signal ACTP and the first row bank selection signal RACTV<0>.

The second logic section 420 may be configured to selectively output a signal UP_LATCH outputted from the first logic section 410 in response to the column pulse signal CASP. For example, the signal UP_LATCH outputted from the first logic section 410 is inputted to a second transmission gate TG2 of the second logic section 420 and selectively outputted. The second transmission gate TG2 is configured to be turned on/off according to the control of an output signal of a second AND gate AND2 which is configured to receive the column pulse signal CASP and the first column bank selection signal CACTV<0>.

The third logic section 430 may be configured to selectively output a signal outputted from the second logic section 420 or the column selection signal YADD<11> as the first and second block enable signals UP_EN and DN_EN under the control of the page size control signal PAGE_{—}2K. Here, the first and second block enable signals UP_EN and DN_EN may be outputted so as to have opposite levels.

The third logic section 430 locally combines the page size control signal PAGE_{—}2K, the column selection signal YADD<11>, and the output signal of the second logic section 420 by using a plurality of NAND gates NAND1, NAND2, and NAND3 and a plurality of inverters INV3 and INV4, and then outputs the combined signal as the first and second block enable signals UP_EN and DN_EN.

For example, when the page size control signal PAGE_{—}2K is at a low level, and bank information during an active operation is identical to bank information during a read/write operation (e.g., the first row bank selection signal RACTV<0> is identical to the first column bank selection signal CACTV<0>), the page size control unit 400 generates the first block enable signal UP_EN and the second block enable signal DN_EN by using the row selection signal XADD<16>.

Furthermore, when the page size control signal PAGE_{—}2K is at a high level, the page size control unit 400 generates the first block enable signal UP_EN and the second block enable signal DN_EN by using the column selection signal YADD<11>.

When the page size control signal PAGE_{—}2K is at the first level (e.g., at a high level), the page size control unit 400 generates the first and second block enable signals UP_EN and DN_EN having a level corresponding to the column selection signal YADD<11>, such that a memory cell having a 2K page size is accessed.

When the page size control signal PAGE_{—}2K is at the second level (e.g., at a low level), the page size control unit 400 generates the first and second block signals UP_EN and DN_EN having a level corresponding to the row selection signal XADD<16>, such that a memory cell having a 1K page size is accessed.

Here, the one row selection signal XADD<16> from the plurality of row selection signals XADD<0:16> is a signal corresponding to the most significant address bit signal TLA<16> of the row address TLA<0:16>. Furthermore, the one column selection signal YADD<11> from the plurality of column selection signals YADD<2:9> and YADD<11> is defined as a signal corresponding to the column address bit signal TLA<11> neighboring the most significant column address bit signal TLA<13> of the column address TLA<2:9>, TLA<11>, and TLA<13>.

As described above, the memory block 700 may include a memory cell array (not illustrated), and can be divided into a plurality of banks. In this disclosed embodiment, however, only first and second page blocks 710 and 720, included in one bank BANK0, are representatively illustrated. For reference, the 1K page size refers to the number of memory cells selected by one row selection signal. Therefore, when the first page block 710 is selected by a row selection signal, 1K memory cells are controlled. Similarly, when the second page block 720 is selected by a row selection signal, 1K memory cells are controlled.

The first page block 710 is configured to enable a plurality of first memory cells selected by the plurality of row selection signals XADD<0:15> in response to the first block enable signal UP_EN. The first page block 710 is also configured to activate data access of the memory cells selected from the plurality of selected first memory cells by the plurality of column selection signals YADD<2:9> and YADD<11> and the option column selection signal YADD_X4.

The second page block 720 is configured to enable a plurality of second memory cells selected by the plurality of row selection signals XADD<0:15> in response to the second block enable signal DN_EN. The second page block 710 is also configured to activate data access of the memory cells selected from the plurality of selected second memory cells by the plurality of column selection signals YADD<2:9> and YADD<11>.

That is, when the page size control signal PAGE_{—}2K becomes a low level, the signal levels of the first and second block enable signals UP_EN and DN_EN are determiend by the row selection signal XADD<16>. Therefore, data for the memory cells of the 1K page may be accessed. At this time, when the bit organization is X4, the option column selection signal YADD_X4 has a level corresponding to the column selection signal YADD<11>. Accordingly, the column access is controlled through the option column selection signal YADD_X4.

Moreover, when the page size control signal PAGE_{—}2K becomes a high level, the signal levels of the first and second block enable signals UP_EN and DN_EN are determined by the column selection signal YADD<11>. Therefore, data for the memory cells of the 2K page may be accessed. At this time, when the bit organization is X4, the option column selection signal YADD_X4 has a level corresponding to the column selection signal YADD<13>. Accordingly, the column access is controlled through the option column selection signal YADD_X4.

As a result, the semiconductor memory apparatus consistent with the present disclosure may freely convert the page size and control the data access according to the bit organization.

TABLE 1

| | X4 | X8 |
|---|---|---|
| 1K PAGE (4 Gb) | ROW_ADDR<0:15> | ROW_ADDR<0:15> |
| | COL_ADDR<0:9, 11> | COL_ADDR<0:9> |
| 1K PAGE (8 Gb) | ROW_ADDR<0:16> | ROW_ADDR<0:16> |
| | COL_ADDR<0:9, 11> | COL_ADDR<0:9> |
| 2K PAGE (8 Gb) | ROW_ADDR<0:15> | ROW_ADDR<0:15> |
| | COL_ADDR<0:9, 11, 13> | COL_ADDR<0:9, 11> |

Table 1 above shows the bit numbers of row and column addresses assigned when the bit organization and the page size of the semiconductor memory apparatus are changed.

The row and column addresses are sequentially inputted through the address multiplexing scheme together with the respective commands. Therefore, in Table 1, a row address latched inside is represented by “ROW_ADDR,” and a column address latched inside is represented by “COL_ADDR.”

Referring to FIG. 1, when the storage capacity of the semiconductor memory apparatus is increased, additional row and column addresses may be assigned to vary the page size. In addition, it may be possible to deal with the change of the bit organization.

In the disclosed embodiment, controlling a page having a limited size is described. In some exemplary embodiments, pages having a variety of sizes may be controlled, and an additional row address bit signal and an additional column address bit signal may be assigned to control the page size according to the bit organization.

While certain embodiments have been described above, it will be understood to those skilled in the art that the embodiments described are by way of example only. Accordingly, the semiconductor memory apparatus described herein should not be limited based on the described embodiments. Rather, the semiconductor memory apparatus described herein should only be limited in light of the claims that follow when taken in conjunction with the above description and accompanying drawings.

What is claimed is:

1. A semiconductor memory apparatus comprising:
a row selection signal generation unit configured to output a row address as a plurality of row selection signals in response to an active pulse signal;
a column control unit configured to selectively assign and output a first or second column address bit signal of a column address as a bit organization control signal based on a page size control signal;
a column selection signal generation unit configured to output the column address as a plurality of column selection signals in response to a column pulse signal, and output the bit organization control signal as an option column selection signal;
a page size control unit configured to generate first and second block enable signals having a level corresponding to one of the plurality of row selection signals or one of the plurality of column selection signals based on the page size control signal;
a first page block configured to enable a plurality of first memory cells selected by the plurality of row selection signals in response to the first block enable signal, and activate data access of memory cells selected among the plurality of selected first memory cells by the plurality of column selection signals and the option column selection signal; and
a second page block configured to enable a plurality of second memory cells selected by the plurality of row selection signals in response to the second block enable signal, and activate data access of memory cells selected among the plurality of selected second memory cells by the plurality of column selection signals and the option column selection signal.

2. The semiconductor memory apparatus according to claim 1, wherein the one of the plurality of row selection signals comprises a row selection signal corresponding to the most significant row address bit signal of the row address.

3. The semiconductor memory apparatus according to claim 1, wherein the one of the plurality of column selection signals comprises a column selection signal corresponding to a column address bit signal neighboring the most significant column address bit signal of the column address.

4. The semiconductor memory apparatus according to claim 1, wherein the column address outputted by the column selection signal generation unit excludes the most significant column address bit signal.

5. The semiconductor memory apparatus according to claim 1, wherein the page size control unit is configured to generate the first and second block enable signals having a level corresponding to one of the plurality of column selection signals when the page size control signal is at a first level, the first and second block enable signals having opposite levels.

6. The semiconductor memory apparatus according to claim 5, wherein the page size control unit is configured to generate the first and second block enable signals having a level corresponding to one of the plurality of row selection signals when the page size control signal is at a second level, the first and second block enable signals having opposite levels.

7. The semiconductor memory apparatus according to claim 6, wherein the one of the plurality of row selection signals comprises a row selection signal corresponding to the most significant row address bit signal of the row address, and the one of the plurality of column selection signals comprises a column selection signal corresponding to a column address bit signal neighboring the most significant address bit signal of the column address.

8. The semiconductor memory apparatus according to claim 1, wherein the page size control unit comprises:
a first logic section configured to selectively output the one of the plurality of row selection signals in response to the active pulse signal;
a second logic section configured to selectively output the signal outputted from the first logic section in response to the column pulse signal; and
a third logic section configured to selectively output the signal outputted from the second logic section or the one of the plurality of column selection signals as the first and second block enable signals in response to the page size control signal, the first and second block enable signals having opposite levels.

9. The semiconductor memory apparatus according to claim 1, wherein the column control unit comprises a logic unit configured to logically combine the page size control signal, the first column address bit signal, and the second column address bit signal and output the combined signals as the bit organization control signal.

10. The semiconductor memory apparatus according to claim 1, further comprising:
a row/column address input unit configured to buffer and store an external row address and an external column address under the control of a clock signal, and output the stored signals as the row address and the column address;
a bank address input unit configured to buffer and store an external bank address according to control of the clock signal, and output the stored signal as a bank address;
a command input unit configured to buffer and store a plurality of external command signals under the control of the clock signal, and output the stored signals as a plurality of command signals; and
an internal command generation unit configured to decode the plurality of command signals and output the decoded signals as an internal command.

11. The semiconductor memory apparatus according to claim 10, wherein the internal command comprises the active pulse signal and the column pulse signal.

12. The semiconductor memory apparatus according to claim 10, wherein the plurality of external command signals comprise /RAS, /CAS, /WE, and /CS<0:2> signals.

13. The semiconductor memory apparatus according to claim 12, wherein the /CS<0:2> signal is used as a chip select signal or external row address bit signal.

14. The semiconductor memory apparatus according to claim 1, wherein the page size control signal comprises a signal outputted from a fuse unit.

15. The semiconductor memory apparatus according to claim 1, wherein the page size control signal is generated by using a signal set in a mode resister set.

16. The semiconductor memory apparatus according to claim 10, wherein the external row address and the external column address are sequentially outputted through an address multiplexing scheme.

17. A semiconductor memory apparatus comprising:
a page size control unit configured to generate first and second block enable signals having a level corresponding to one of a plurality of row selection signals or one of a plurality of column selection signals based on a page size control signal;
a first page block configured to enable a plurality of first memory cells selected by the plurality of row selection signals in response to the first block enable signal, and activate data access of memory cells selected among the plurality of selected first memory cells by the plurality of column selection signals and the option column selection signal; and
a second page block configured to enable a plurality of second memory cells selected by the plurality of row selection signals in response to the second block enable signal, and activate data access of memory cells selected among the plurality of selected second memory cells by the plurality of column selection signals and the option column selection signal.

18. The semiconductor memory apparatus according to claim 17, wherein the one of the plurality of row selection signals comprises a row selection signal corresponding to the most significant row address bit signal of a row address.

19. The semiconductor memory apparatus according to claim 18, wherein the one of the plurality of column selection signals comprises a column selection signal corresponding to a column address bit signal neighboring the most significant column address bit signal of a column address.

20. The semiconductor memory apparatus according to claim 19, wherein the row address and the column address are sequentially inputted through an address multiplexing scheme.

21. The semiconductor memory apparatus according to claim 17, wherein the page size control unit is configured to generate the first and second block enable signals having a level corresponding to one of the plurality of column selection signals when the page size control signal is at a first level, the first and second block enable signals having opposite levels.

22. The semiconductor memory apparatus according to claim 21, wherein the page size control unit is configured generate the first and second block enable signals having a level corresponding to one of the plurality of row selection signals when the page size control signal is at a second level, the first and second block enable signals having opposite levels.

23. The semiconductor memory apparatus according to claim 22, wherein the one of the plurality of row selection signals comprises a row selection signal corresponding to the most significant row address bit signal of a row address, and the one of the plurality of column selection signals comprises a column selection signal corresponding to a column address bit signal neighboring the most significant column address bit signal of a column address.

24. The semiconductor memory apparatus according to claim 17, wherein the page size control unit comprises:
a first logic section configured to selectively output the one of the plurality of row selection signals in response to an active pulse signal;
a second logic section configured to selectively output the signal outputted from the first logic section in response to a column pulse signal; and
a third logic section configured to selectively output the signal outputted from the second logic section or the one of the pluralities of column selection signals as the first and second block enable signals according to the page size control signal, the first and second block enable signals having opposite levels.

25. The semiconductor memory apparatus according to claim 17, wherein the page size control signal comprises a signal outputted from a fuse unit.

26. The semiconductor memory apparatus according to claim 17, wherein the page size control signal is generated by using a signal set in a mode register set.

27. The semiconductor memory apparatus according to claim 17, wherein the option column selection signal comprises a signal generated based on a bit organization control signal.

28. The semiconductor memory apparatus according to claim 27, wherein the bit organization control signal comprises a signal generated by using any one column address bit signal of a column address based on the page size control signal.
